(19) United States
(12) Patent Application Publication
(10) Pub. No.: US 2026/0244117 A1
(43) Pub. Date: Aug. 20, 2026

(54) RETICLE TRANSFER DEVICE WITH RETICLE PATTERN FACING DOWNWARD

(71) Applicant: HUA YANG Precision Machinery Co., Ltd., Tainan City (TW)

(72) Inventors: Hsien-Te HSIAO, Tainan City (TW); Meng-Ju LIN, Tainen City (TW); Kun-Feng LIN, Tainan City (TW)

(21) Appl. No.: 19/057,386

(22) Filed: Feb. 19, 2025

(51) Int. Cl. G03F 7/00

(52) U.S. Cl. CPC G03F 7/70741

(57) ABSTRACT

Provided is a reticle transfer device with a reticle pattern facing downward, including: a base; an X-oriented moving table; a Y-oriented moving table; a jaw assembly having two gripping units; a pushing positioning assembly having a stationary unit and a pushing unit; a lifting rotary table; and a supporting table having four supporting components. During its ascent and descent, the supporting table assumes a supporting position, a gripping position, and a bottom position. When the supporting table is at the gripping position, the two gripping units grip or release the reticle on the supporting table, and the pushing unit pushes or refrains from pushing the reticle.

### BACKGROUND OF THE INVENTION

### Technical Field

The present disclosure relates to reticle transfer technology, and more particularly to a reticle transfer device with a reticle pattern facing downward.

### Description of Related Art

The inspection of reticles entails moving the reticles on a machine. Taiwan patent I609235 discloses a reticle inspection device and method. Regarding reticle transfer technology, Taiwan patent I609235 discloses a moving platform undergoing displacement in a first direction, a rotating platform undergoing displacement in a second direction, and a supporting platform for supporting the reticle. Therefore, Taiwan patent I609235 discloses moving a reticle in a first direction and moving the reticle in a second direction perpendicular to the first direction, i.e., moving the reticle in X-direction and Y-direction. However, Taiwan patent I609235 does not disclose any specific technical features about moving the reticle in the other directions.

Furthermore, according to Taiwan patent I609235, the reticle being inspected has a patterned surface that faces upward, resulting in a drawback: although the patterned surface of the reticle is mostly covered with a protective film, a portion of the patterned surface is exposed in the absence of any protective film. It is of vital importance that the pattern itself is not contaminated by dust. On the other hand, the protective film is expensive and thus must not be contaminated by dust. However, even in a cleanroom, it is inevitable that some dust can settle, predisposing upward-facing patterned surfaces and protective films to dust contamination in the course of reticle inspection and resultant issues about rinsing, drying, interference with inspection, and faulty inspection results.

Therefore, it is imperative to not only enable reticles to be transferred while their patterned surfaces are facing downward, but also provide a different or even better solution to the aforesaid issues in terms of structural features when compared with prior art.

### BRIEF SUMMARY OF THE INVENTION

It is an objective of the disclosure to provide a reticle transfer device with a reticle pattern facing downward, allowing a reticle to have its patterned surface facing downward while being transferred.

Another objective of the disclosure is to provide a reticle transfer device with a reticle pattern facing downward, transferring a reticle with a downward-facing patterned surface and technical features different from those of prior art.

To achieve the above and other objectives, the disclosure provides a reticle transfer device with a reticle pattern facing downward, comprising: a base; an X-oriented moving table disposed at the base and driven to move in X-direction across the base; a Y-oriented moving table disposed at the X-oriented moving table and driven to move in Y-direction across the X-oriented moving table; a jaw assembly having two gripping units facing each other and disposed on the Y-oriented moving table, the two gripping units gripping two opposing sides of a reticle rectangular in shape to grip and hold the reticle; a pushing positioning assembly having a stationary unit and a pushing unit disposed at the Y-direction moving table, the pushing unit having a pushing block for pushing the reticle to cause the reticle to abut against the stationary unit so as to be positioned in place; a lifting rotary table disposed at the base and driven to move in Z-direction across the base; and a supporting table disposed at the lifting rotary table, adapted to ascend in Z-direction, descend in Z-direction, and rotate horizontally along with the lifting rotary table, having four supporting components, and adapted to support the reticle, the reticle having a patterned surface facing downward, the four supporting components supporting and abutting against four sides of a bottom of the reticle, wherein, during its ascent and descent, the supporting table assumes a supporting position, a gripping position, and a bottom position, the supporting position allowing the four supporting components to be higher than the two gripping units, the gripping position allowing the reticle to be between the two gripping units to allow the two gripping units to grip or release the reticle on the supporting table and allow the pushing unit to push or refrain from pushing the reticle, and the bottom position allowing the four supporting components to be lower than the two gripping units.

Therefore, the disclosure not only enables reticles to be transferred while their patterned surfaces are facing downward, but also provides a different solution to the aforesaid issues in terms of structural features when compared with prior art.

### BRIEF DESCRIPTION OF THE SEVERAL VIEWS OF THE DRAWINGS

FIG. 1 is a perspective view of the first preferred embodiment of the disclosure.

FIG. 2 is a cutaway view of the first preferred embodiment of the disclosure.

FIG. 3 is another cutaway view of the first preferred embodiment of the disclosure, but the cutaway view in FIG. 3 is taken at an angle approximately 90° different from the view angle of the cutaway view in FIG. 2.

FIG. 4 is yet another cutaway view viewed from bottom to top according to the first preferred embodiment of the disclosure.

FIG. 5 is an exploded view showing a jaw assembly and a pushing positioning assembly according to the first preferred embodiment of the disclosure.

FIG. 6 is a perspective view showing a Z-oriented moving platform and a supporting table according to the first preferred embodiment of the disclosure.

FIG. 7 is a schematic view showing the supporting table, the jaw assembly and the pushing positioning assembly according to the first preferred embodiment of the disclosure.

FIG. 8 is a schematic view of the first preferred embodiment of the disclosure.

FIG. 9 is another schematic view of the first preferred embodiment of the disclosure.

FIG. 10 is yet another schematic view of the first preferred embodiment of the disclosure.

FIG. 11 is still yet another schematic view of the first preferred embodiment of the disclosure.

FIG. 12 is a further schematic view of the first preferred embodiment of the disclosure.

FIG. 13 is a further schematic view of the first preferred embodiment of the disclosure.

FIG. 14 is a further schematic view of the first preferred embodiment of the disclosure.

FIG. 15 is a further schematic view of the first preferred embodiment of the disclosure.

FIG. 16 is a perspective view of the second preferred embodiment of the disclosure.

### DETAILED DESCRIPTION OF THE INVENTION

Objectives, features, and advantages of the disclosure are herein illustrated with preferred embodiments, depicted with drawings, and described below.

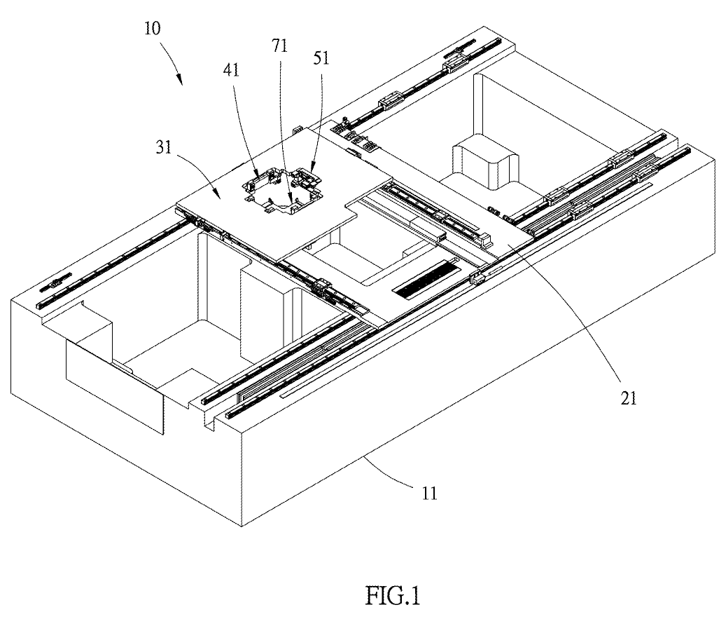

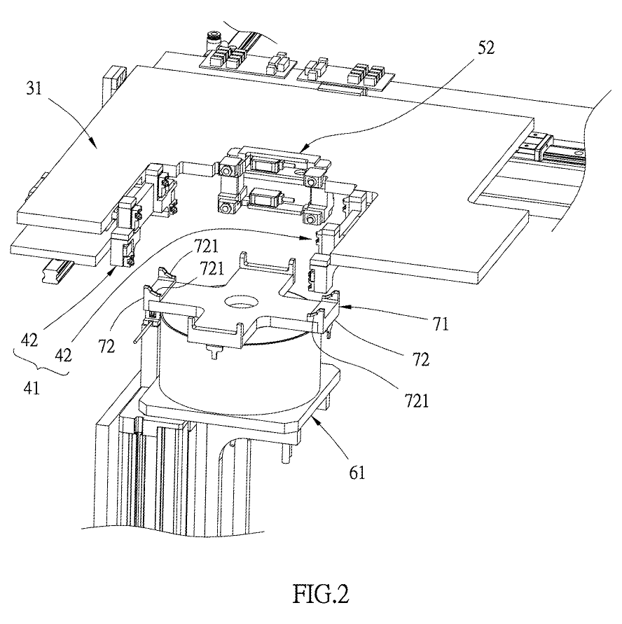

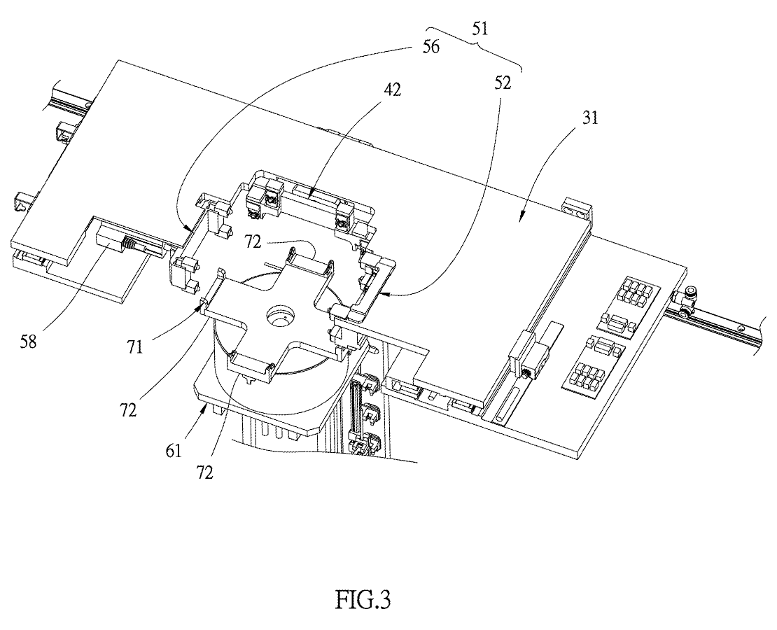

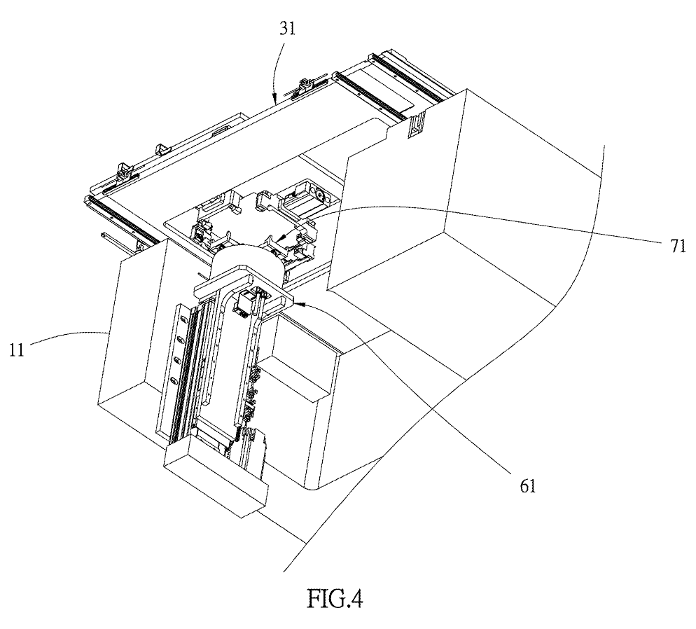

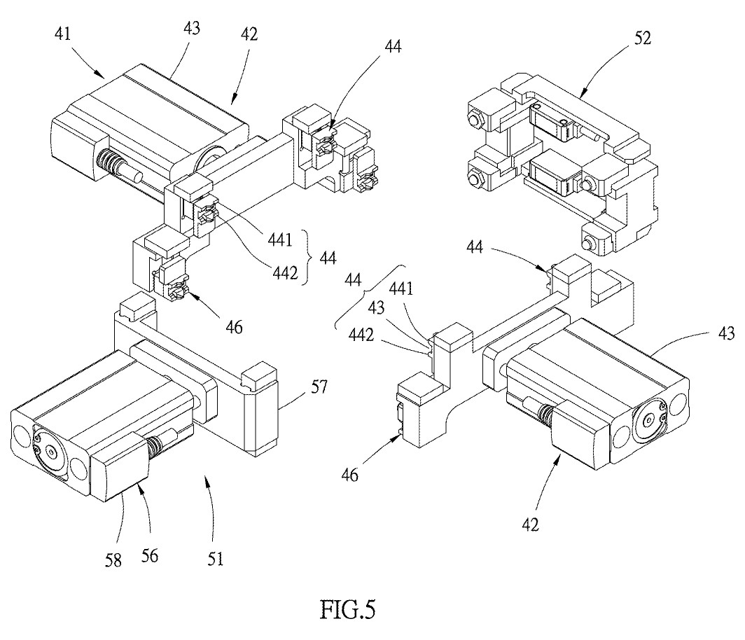

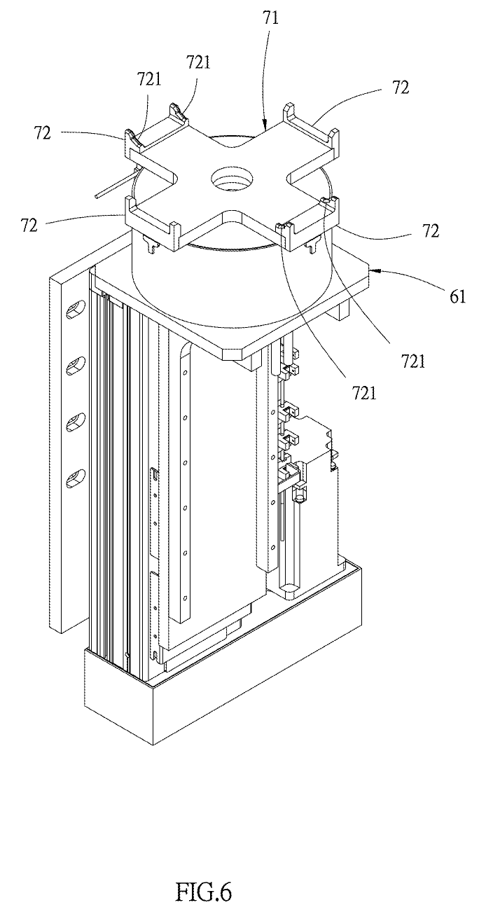

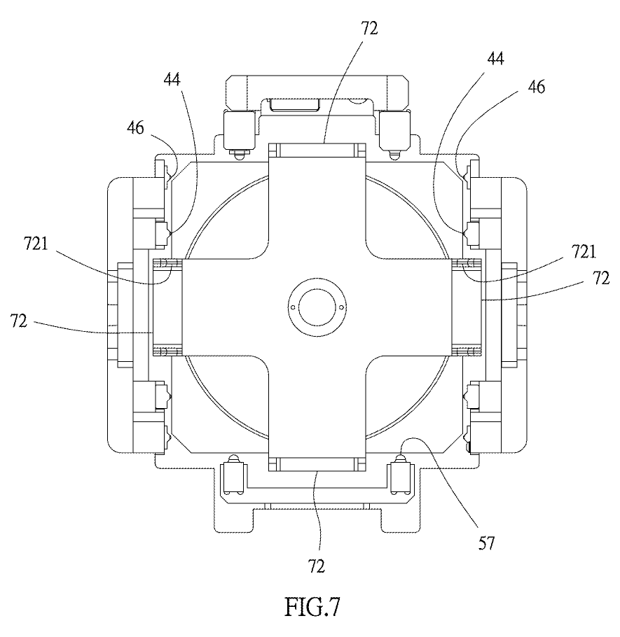

As shown in FIG. 1 through FIG. 7, the first preferred embodiment of the disclosure provides a reticle transfer device with a reticle pattern facing downward 10, essentially comprising a base 11, an X-oriented moving table 21, a Y-oriented moving table 31, a jaw assembly 41, a pushing positioning assembly 51, a lifting rotary table 61, and a supporting table 71.

The X-oriented moving table 21 is disposed at the base 11 and driven to move in X-direction across the base 11. This involves, in practice, using a conventional linear slide rail or ball screw operating in conjunction with a driving motor – but these do not constitute an essential technical feature of the disclosure and thus, for the sake of brevity, are not reiterated.

The Y-oriented moving table 31 is disposed at the X-oriented moving table 21 and driven to move in Y-direction across the X-oriented moving table 21. In an embodiment of the disclosure, the Y-oriented moving table 31 uses components similar to those of the X-oriented moving table 21 – but these do not constitute an essential technical feature of the disclosure and thus, for the sake of brevity, are not reiterated.

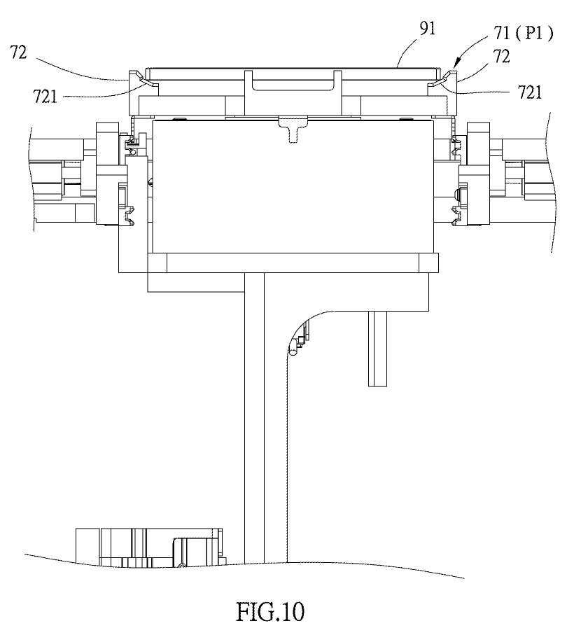

The jaw assembly 41 has two opposing gripping units 42 disposed at the Y-oriented moving table 31. The two gripping units 42 grip two opposing sides of a reticle 91 (shown in FIG. 10) rectangular in shape to grip and hold the reticle 91. In the first embodiment, The gripping units 42 each have a gripping actuator 43 and two jaws 44. The gripping actuator 43 of each of the gripping units 42 drives each of the two jaws 44 thereof to move toward or move away from the other one of the gripping units 42. The two jaws 44 of each of the gripping units 42 face the two jaws 44 of the other one of the gripping units 42. In the first embodiment, each jaw 44 has an upper clamping element 441 and a lower clamping element 442, with the upper and lower clamping elements 441, 442 opposing each other vertically and forming therebetween an opening 443 that gradually opens outward.

Furthermore, the gripping units 42 each further have two lower-level jaws 46. The two lower-level jaws 46 are lower than the two jaws 44. The two lower-level jaws 46 of each of the gripping units 42 oppose the two lower-level jaws 46 of the other one of the gripping units 42. The lower-level jaws 46 are structurally similar to the jaws 44. The two lower-level jaws 46 of each of the gripping units 42 do not vertically overlap the two jaws 44 above, allowing the jaws 44 or the lower-level jaws 46 to adjust their horizontal relationship more conveniently.

The pushing positioning assembly 51 has a stationary unit 52 and a pushing unit 56 disposed at the Y-oriented moving table 31. The pushing unit 56 has a pushing block 57 for pushing the reticle 91 to cause the reticle 91 to abut against the stationary unit 52 so as to be positioned in place. In the first embodiment, the pushing unit 56 has a pushing actuator 58 for driving the pushing block 57 to push and abut against the reticle 91, with the stationary unit 52 being two stationary bumps.

The lifting rotary table 61 is disposed at the base 11 and driven to move in Z-direction across the base 11. In an embodiment of the disclosure, a component for use with the lifting rotary table 61 can be a linear slide rail, servo motor, or any other known component and thus is, for the sake of brevity, not reiterated. X-direction and Y-direction refer to two perpendicular directions on the horizontal plane, whereas Z-direction refers to the direction perpendicular to the horizontal plane.

The supporting table 71 is disposed at the lifting rotary table 61 and adapted to ascend in Z-direction, descend in Z-direction, and rotate horizontally along with the lifting rotary table 61. The supporting table 71 has four supporting components 72. The supporting table 71 supports the reticle 91. The reticle 91 has a patterned surface (not shown) that faces downward. Two opposing ones of the supporting components 72 have two oblique walls 721 respectively whereby the supporting components 72 support and abut against two opposing edges of the bottom of the reticle 91. An oblique surface of the oblique wall 721 is in contact with the reticle 91 to minimize contact surface area. In the first embodiment, the jaws 44 of the gripping units 42 do not interfere with the supporting components 72 of the supporting table 71. The patterned surface of the reticle 91 is protected with a protective film. In a variant embodiment, the patterned surface lacks a protective film.

During its ascent and descent, the supporting table 71 assumes a supporting position P1, a gripping position P2, a lower-level gripping position P3, and a bottom position P4. When the supporting table 71 is at the supporting position P1, the four supporting components 72 are higher than the two gripping units 42. When the supporting table 71 is at the gripping position P2, the gripping position P2 allows the reticle 91 to be positioned between the two gripping units 42, allows the two gripping units 42 to grip or release the reticle 91 on the supporting table 71, allows the pushing unit 56 to push or refrain from pushing the reticle 91, and allows the two jaws 44 of each of the gripping units 42 to flank the corresponding one of the supporting components 72. When the supporting table 71 is at the bottom position P4, the four supporting components 72 are lower than the two gripping units 42. When the supporting table 71 is at the lower-level gripping position P3, the two gripping units 42 can grip or release the reticle 91 on the supporting table 71. Furthermore, when the supporting table 71 is at the lower-level gripping position P3, the two lower-level jaws 46 of each of the gripping units 42 flank the corresponding one of the supporting components 72.

The structural features of the first embodiment are described above. The dynamic features of the first embodiment are described below.

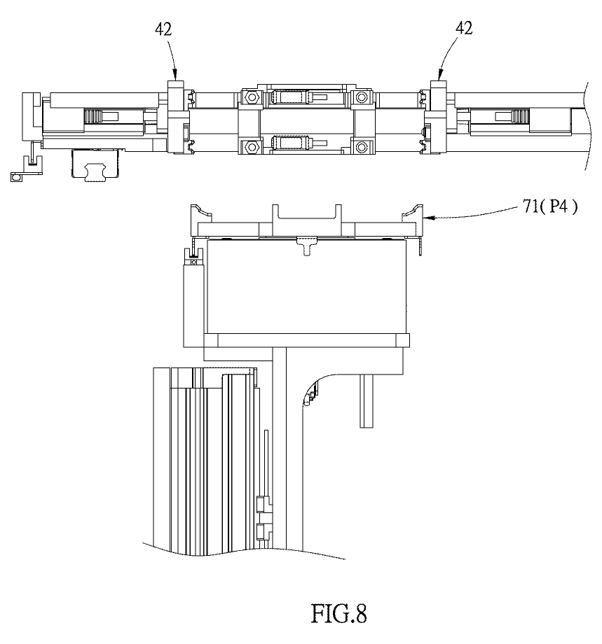

As shown in FIG. 8, when not supporting the reticle 91, the supporting table 71 is located at the bottom position P4.

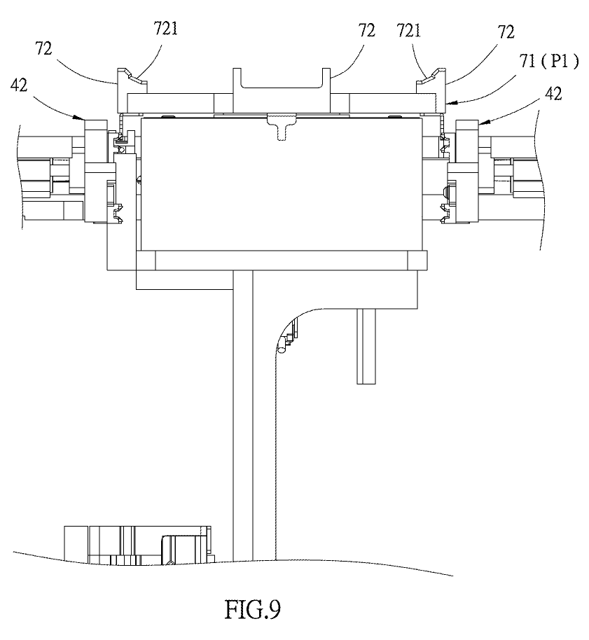

As shown in FIG. 9, when it is necessary to support the reticle 91, the supporting table 71 is moved up to the supporting position P1. At this point in time, the four supporting components 72 are higher than the two gripping units 42. As shown in FIG. 10, a robotic arm (not shown) places the reticle 91 with the patterned surface (not shown) facing down onto the supporting table 71; meanwhile, the oblique walls 721 of the two supporting components 72 support and abut against the four sides of the bottom of the reticle 91. At this point in time, if the reticle 91 needs to be rotated to a certain angle, the supporting table 71 will horizontally rotate the reticle 91, for example, by 90° or 270°.

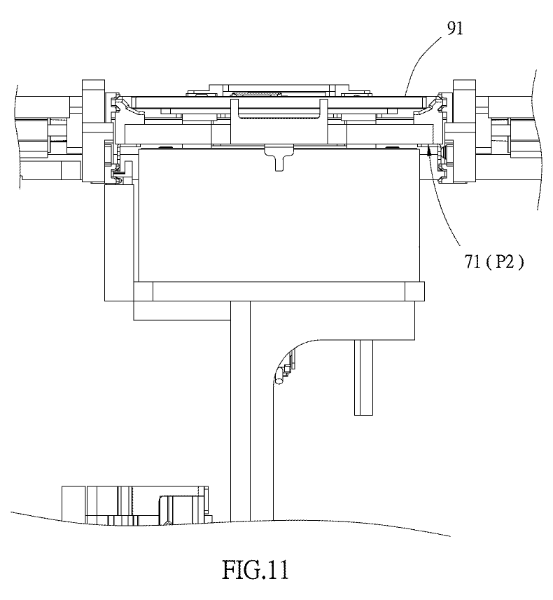

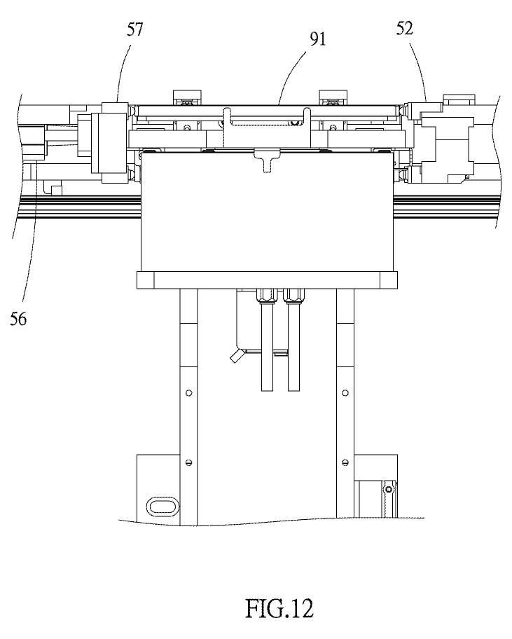

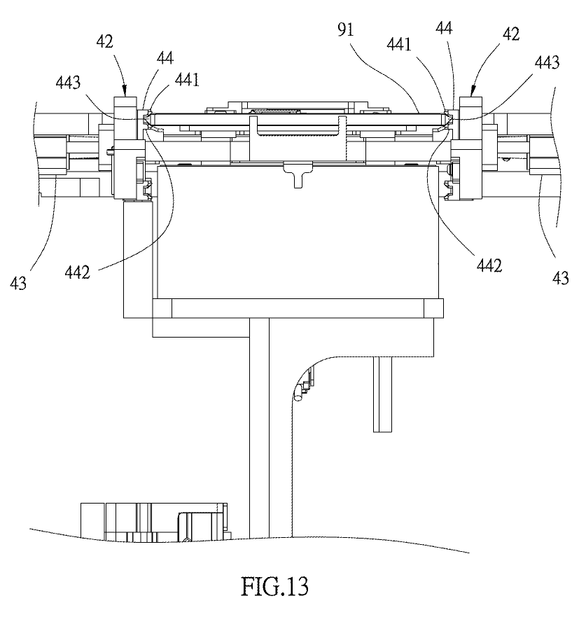

As shown in FIG. 11, the supporting table 71 is moved down to the gripping position P2. As shown in FIG. 12, the pushing unit 56 drives the pushing block 57 to push the reticle 91 to cause the reticle 91 to abut against the stationary unit 52, allowing the reticle 90 to be positioned in place. As shown in FIG. 13, in each of the two gripping units 42, the gripping actuator 43 drives the two jaws 44 to move toward each other to allow the opening 443 between the upper clamping element 441 and the lower clamping element 442 of each of the jaws 44 to match an edge of the reticle 91, allowing the upper clamping element 441 and the lower clamping element 442 to grip the reticle 91. At this point in time, all the four sides of the reticle 91 are gripped and fixed in place, attaining a stable gripping state.

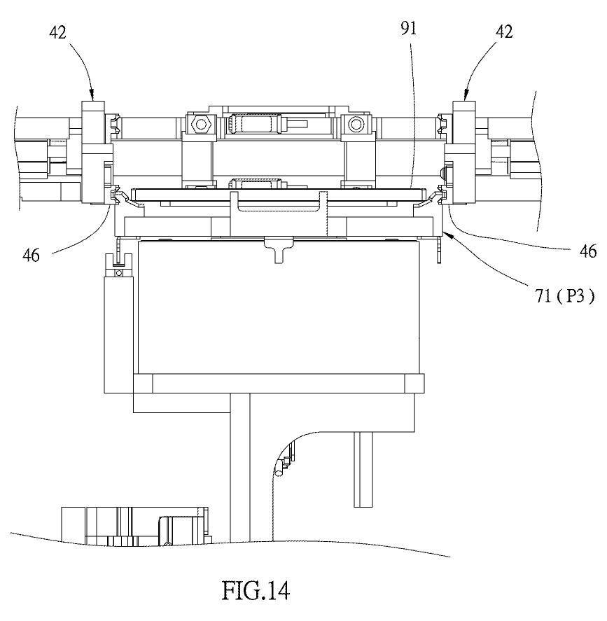

As shown in FIG. 14, if the reticle 91 has to be inspected at a lower position, the supporting table 71 need not be at the gripping position P2 in order to be gripped; instead, the supporting table 71 can be at the lower-level gripping position P3, and thus the pushing unit 56 drives the pushing block 57 to push the reticle 91 to cause the reticle 91 to abut against the stationary unit 52 so as to be positioned in place (shown in FIG. 12), allowing the two lower-level jaws 46 of each of the gripping units 42 to approach and grip the reticle 91 or retract and release the reticle 91. The lower-level gripping position P3 allows the reticle 91 to be gripped at different heights in order to be inspected with inspection devices (not shown) that differ in visual range or focal length.

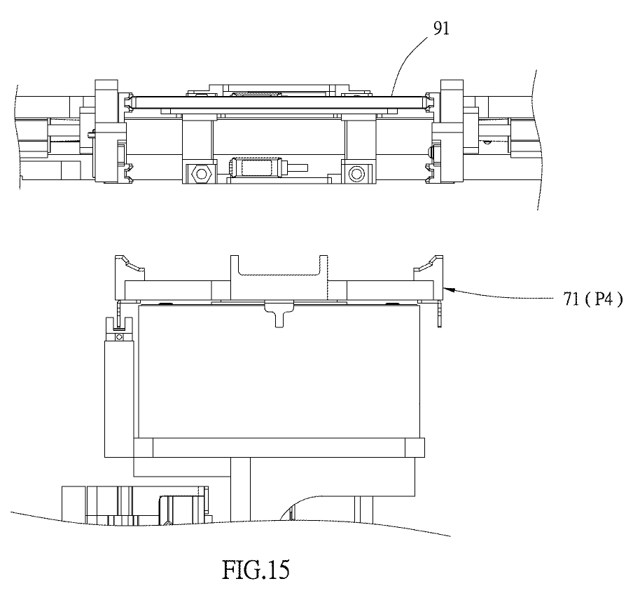

As shown in FIG. 15, once the reticle 91 is gripped, the supporting table 71 will no longer need to support the reticle 91 and thus can be moved down to the bottom position P4. At this point in time, the reticle 91 is gripped and thus is free of interference from the supporting table 71 such that the X-oriented moving table 21 and the Y-oriented moving table 31 can be controllably moved, allowing the reticle 91 to move to an inspection position.

Upon completion of inspection, the reticle 91 can be released from the two gripping units 42 by performing the above operations in reverse order. After that, the supporting table 71 is moved up to the supporting position P1, and then the reticle 91 is taken out by the robotic arm (not shown).

Therefore, according to the first embodiment, the reticle 91 is transferred by gripping the edges of the reticle 91 with the pushing positioning assembly 51 and the jaw assembly 41 without providing support to or coming into contact with the patterned surface at the bottom of the reticle 91. Thus, the first embodiment eliminates the need to place components at the bottom of reticle 91 that may obstruct inspection while still enabling the reticle 91 with the patterned surface facing downward to be transferred and preventing the contamination that may otherwise be caused by falling dust above. Furthermore, the first embodiment is structurally different from the prior art and thus is advantageously characterized by simple operations and stable gripping.

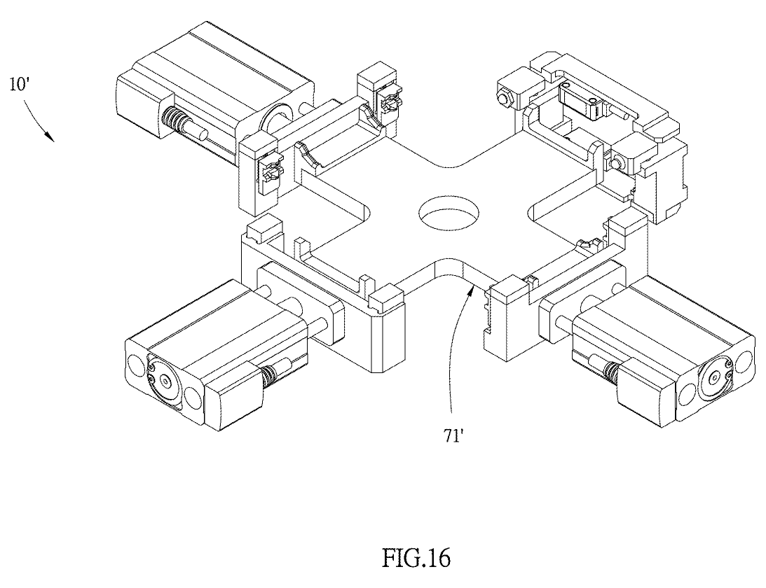

As shown in FIG. 16, the second preferred embodiment of the disclosure provides a reticle transfer device with a reticle pattern facing downward 10’ and is mainly similar to the first preferred embodiment, with the difference as follows:

In the second preferred embodiment, the positions assumed by the supporting table 71’ during its ascent and descent do not include the lower-level gripping position P3, and the two lower-level jaws 46 are dispensed with.

Owing to the aforesaid structural features, the height that enables the reticle 91 (shown in FIG. 10) to be inspected is restricted to the gripping position P2 (shown in FIG. 11) of the first embodiment and thus still falls within the scope of the claims of the disclosure under the condition of satisfying user needs.

The other structural features and achievable advantages of the second embodiment are roughly similar to those of the first embodiment and thus, for the sake of brevity, are not reiterated.

The disclosure is disclosed above by embodiments. The embodiments shall not be interpreted as restrictive of the scope of the claims of the disclosure. Thus, all simple equivalent variations and modifications made to the aforesaid embodiments according to the claims and detailed description of the disclosure shall be deemed to fall within the scope of the claims of the disclosure.

What is claimed is:

1. A reticle transfer device with a reticle pattern facing downward, comprising:
a base;
an X-oriented moving table disposed at the base and driven to move in X-direction across the base;
a Y-oriented moving table disposed at the X-oriented moving table and driven to move in Y-direction across the X-oriented moving table;
a jaw assembly having two gripping units facing each other and disposed on the Y-oriented moving table, the two gripping units gripping two opposing sides of a reticle rectangular in shape to grip and hold the reticle;
a pushing positioning assembly having a stationary unit and a pushing unit disposed at the Y-direction moving table, the pushing unit having a pushing block for pushing the reticle to cause the reticle to abut against the stationary unit so as to be positioned in place;
a lifting rotary table disposed at the base and driven to move in Z-direction across the base; and
a supporting table disposed at the lifting rotary table, adapted to ascend in Z-direction, descend in Z-direction, and rotate horizontally along with the lifting rotary table, having four supporting components, and adapted to support the reticle, the reticle having a patterned surface facing downward, the four supporting components supporting and abutting against four sides of a bottom of the reticle,
wherein, during its ascent and descent, the supporting table assumes a supporting position, a gripping position, and a bottom position, the supporting position allowing the four supporting components to be higher than the two gripping units, the gripping position allowing the reticle to be between the two gripping units to allow the two gripping units to grip or release the reticle on the supporting table and allow the pushing unit to push or refrain from pushing the reticle, and the bottom position allowing the four supporting components to be lower than the two gripping units.

2. The reticle transfer device with a reticle pattern facing downward according to claim 1, wherein each of the gripping units has a gripping actuator and two jaws, the gripping actuator driving each of the two jaws to move toward or move away from the other one of the gripping units, and the two jaws of each of the gripping units face the two jaws of the other one of the gripping units.

3. The reticle transfer device with a reticle pattern facing downward according to claim 2, wherein the jaws of the gripping units do not interfere with the supporting components of the supporting table.

4. The reticle transfer device with a reticle pattern facing downward according to claim 3, wherein the two jaws of each of the gripping units flank the corresponding one of the supporting components when the supporting table is at the gripping position.

5. The reticle transfer device with a reticle pattern facing downward according to claim 2, wherein the jaws each have an upper clamping element and a lower clamping element, with the upper and lower clamping elements opposing each other vertically and forming therebetween an opening that gradually opens outward.

6. The reticle transfer device with a reticle pattern facing downward according to claim 2, wherein during its ascent and descent the supporting table further assumes a lower-level gripping position that allows the two gripping units to grip or release the reticle on the supporting table, and the gripping units each further have two lower-level jaws being lower than the two jaws and facing the two lower-level jaws of the other one of the gripping units.

7. The reticle transfer device with a reticle pattern facing downward according to claim 6, wherein the two lower-level jaws of each of the gripping units do not vertically overlap the two jaws above, and the lower-level gripping position allows the two lower-level jaws of each of the gripping units to flank the corresponding one of the supporting components.

8. The reticle transfer device with a reticle pattern facing downward according to claim 1, wherein the pushing unit has a pushing actuator for driving the pushing block to push and abut against the reticle.

9. The reticle transfer device with a reticle pattern facing downward according to claim 1, wherein two opposing ones of the supporting components have two oblique walls respectively whereby the supporting components support and abut against two opposing edges of the bottom of the reticle.
